(19) United States
(12) Patent Application Publication
(10) Pub. No.: US 2018/0114864 A1
(43) Pub. Date: Apr. 26, 2018

(54) THIN-FILM TRANSISTOR, METHOD FOR FABRICATING THE SAME, ARRAY SUBSTRATE AND DISPLAY PANEL CONTAINING THE SAME

(71) Applicant: BOE TECHNOLOGY GROUP CO., LTD, Beijing (CN)

(72) Inventor: XIANG LIU, Beijing (CN)

(21) Appl. No.: 15/122,917

(22) PCT Filed: Feb. 22, 2016
(86) PCT No.: PCT/CN2016/074263

§ 371 Date: Aug. 31, 2016

(30) Foreign Application Priority Data
Aug. 24, 2015 (CN) 2015-10524296.1

(51) Int. Cl. H01L 29/786; H01L 29/66; H01L 27/12

(52) U.S. Cl. CPC H01L 29/78618; H01L 29/7869; H01L 29/66969; G02F 1/1368; H01L 27/1288; H01L 27/1225; H01L 27/1248; H01L 27/127

(57) ABSTRACT

The present disclosure provides a thin-film transistor (TFT). The TFT includes a gate electrode on a substrate; a gate insulating layer covering the gate electrode; and an active layer having a channel region between a source and drain electrode. The TFT also includes the source and drain electrode on the gate insulating layer; a protection layer on the source and drain electrode; and an opening through the protection layer and the source and drain electrode, the opening exposing the channel region.

### CROSS-REFERENCES TO RELATED APPLICATIONS

This PCT patent application claims priority of Chinese Patent Application No. 201510524296.1, filed on Aug. 24, 2015, the entire content of which is incorporated by reference herein.

### TECHNICAL FIELD

The present invention generally relates to the display technologies and, more particularly, relates to a thin-film transistor and its fabrication method, an array substrate, and a display panel.

### BACKGROUND

As flat screen display technology advances, users are becoming more demanding on flat screen display panels. Particularly, demands on the flat display screen require thin-film transistors (TFTs) to have higher mobility. Existing TFTs are amorphous silicon-based TFTs. That is, the active layer of a TFT is made of amorphous silicon. The amorphous silicon often has low mobility. For example, the electron mobility of amorphous silicon is about 0.1 to 1 cm²V⁻¹s⁻¹, which is not desirable for the current flat screen display technology. Thus, low temperature polysilicon (LTPS) TFTs and oxide TFTs have been developed.

The active layer of a LTPS TFT is made of low temperature polysilicon. Low temperature polysilicon refers to the polysilicon formed by converting amorphous silicon to polysilicon at a sufficiently low temperature. The carrier mobility of a LTPS TFT is high for about 100 to 500 cm²V⁻¹s⁻¹. However, it is often difficult to form uniformed LTPS TFTs. As a result, in the fabrication of large-sized display panels, it is hard to overcome the issues caused by non-uniformity of the LTPS TFTs.

The active layer of an oxide TFT is made of a semiconductor oxide material. In a large-sized display panel, oxide TFTs often have desirable uniformity. Meanwhile, the carrier mobility of an oxide TFT is about 10 cm²V⁻¹s⁻¹. Thus, oxide TFTs are more desirable for large-sized display panels because the oxide TFTs have high mobility, high uniformity, and transparency. The fabrication process to form the oxide TFTs is also simpler.

Currently, when fabricating oxide TFTs, the source and drain layer are often formed after the formation of the active layer, which is made of a metal oxide material. However, the active layer is often damaged when etching to form the source and drain layer. Etchant solution can be adjusted to reduce the damages but the damages still exist. The performance of the formed oxide TFTs may be degraded. The damages can even cause an oxide TFT to lose its switching functions.

The disclosed thin-film transistors and fabrication methods, array substrates, and display panels are directed to at least partially alleviate one or more problems set forth above and to solve other problems in the art.

### BRIEF SUMMARY OF THE DISCLOSURE

The present disclosure provides a thin-film transistor and its fabrication method, an array substrate, and a display panel. In the disclosed TFT, a protection layer is included and is not in contact with the semiconductor oxide layer. The semiconductor properties of the semiconductor oxide layer in the TFTs can be maintained and the performance of the formed oxide TFTs can be improved.

One aspect of the present disclosure includes a thin-film transistor (TFT). The TFT includes a gate electrode on a substrate; a gate insulating layer covering the gate electrode; and an active layer having a channel region between a source and drain electrode. The TFT also includes the source and drain electrode on the gate insulating layer; a protection layer on the source and drain electrode; and an opening through the protection layer and the source and drain electrode, the opening exposing the channel region.

Optionally, the protection layer is made of a non-metal material, different from a material for forming the source and drain electrode.

Optionally, the protection layer is made of one or more of an insulating metal oxide, SiNₓ, SiON, SiC, and an organic material.

Optionally, a thickness of the protection layer is between about 200 Å to about 2000 Å.

Optionally, the TFT further includes a resin layer on the protection layer, an orthogonal projection of the resin layer on the substrate overlapping with an orthogonal projection of the protection layer on the substrate.

Optionally, a thickness of the resin layer is between about 1.0 to about 4.0 μm.

Optionally, an orthogonal projection of the source and drain electrode on the substrate overlaps with an orthogonal projection of the protection layer on the substrate.

Optionally, the TFT further includes a passivation layer covering the protection layer and the channel region.

Optionally, the TFT further includes a barrier layer between the active layer and the source and drain electrode, the barrier layer exposing the channel region.

Optionally, a material for forming the barrier layer has high etch selectivity over a material for forming the active layer and a material for forming the source and drain electrode.

Another aspect of the present disclosure provides an array substrate, comprising one or more of the disclosed TFTs.

Another aspect of the present disclosure provides a display panel, including the disclosed array substrate.

Another aspect of the present disclosure provides a method for fabricating a thin-film transistor (TFT). The method includes forming a gate electrode on a substrate and a gate insulating layer covering the gate electrode; forming an active film on the gate insulating layer for forming an active layer, the active layer having a channel region between a source and drain electrode; and forming a source and drain electrode film on the gate insulating layer for forming the source and drain electrode. The method also includes forming a protection film on the source and drain electrode film for forming a protection layer; and forming an opening through the source and drain electrode film and the protection film, the opening corresponding to the channel region of the active layer.

Optionally, the method further includes forming a barrier film between the active film and the source and drain electrode film.

Optionally, a material for forming the barrier film has high etch selectivity over a material for forming the active film and a material for forming the source and drain electrode film.

Optionally, the barrier layer is made of Mo, Ti, W, Mo alloys, Ti alloys, or a combination thereof.

Optionally, the active layer, the source and drain electrode and the protection layer are formed by one single patterning process.

Optionally, the opening includes a first opening and a second opening, the first opening being formed by removing a portion of the source and drain electrode film that corresponds to the channel region of the active layer, and the second opening being formed by removing a portion of the protection film that corresponds to the channel region of the active layer.

Optionally, the method further includes: removing a portion of the barrier layer to expose the channel region of the active layer after forming the first opening and the second opening.

Optionally, a halftone mask, a gray-scale mask, or a combination of a halftone mask and a gray-scale mask is used to form the active layer, the source and drain electrode, and the protection layer.

Optionally, the method further includes: before forming the first opening, forming the active layer and patterning the source and drain electrode film and the protection film.

Optionally, the method further includes: forming a resin layer on the protection layer, wherein the resin layer, the protection layer, and the opening are formed through one patterning process.

Optionally, the resin layer is used as a mask for forming the protection layer and the opening.

Optionally, the method according further includes: forming a passivation layer on the protection layer, the passivation layer covering at least the protection layer and the channel region of the active layer corresponding to the opening.

Optionally, the passivation layer covers at least the protection layer, the gate insulating layer, and the channel region of the active layer corresponding to the opening.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1(a) illustrates a cross-sectional view of an exemplary TFT according to a first embodiment of the present disclosure;

FIG. 1(b) illustrates a cross-sectional view of a source and drain electrode, and a protection layer in an exemplary TFT according to the first embodiment of the present disclosure;

FIG. 1(c) illustrates a cross-sectional view of the protection layer and related structures at a certain stage during formation of the exemplary TFT according to the first embodiment of the present disclosure;

FIG. 1(d) illustrates a cross-sectional view of another structure at a certain stage during formation of the exemplary TFT according to the first embodiment of the present disclosure;

FIG. 2(a) illustrates another cross-sectional view of another structure at a certain stage during formation of the exemplary TFT according to the first embodiment of the present disclosure;

FIG. 2(b) illustrates another cross-sectional view of another structure at a certain stage during formation of the exemplary TFT according to the first embodiment of the present disclosure;

FIG. 2(c) illustrates another cross-sectional view of another structure at a certain stage during formation of the exemplary TFT according to the first embodiment of the present disclosure;

FIG. 2(d) illustrates another cross-sectional view of the another structure at a certain stage during formation of the exemplary TFT according to the first embodiment of the present disclosure;

FIG. 3 illustrates an exemplary flow chart of a fabrication process of another exemplary TFT according to a second embodiment of the present disclosure; and

FIGS. 4(a)-4(h) illustrate exemplary structures at various stages during the formation of another exemplary TFT according to the second embodiment of the present disclosure.

### DETAILED DESCRIPTION

For those skilled in the art to better understand the technical solution of the invention, reference will now be made in detail to exemplary embodiments of the invention, which are illustrated in the accompanying drawings. Wherever possible, the same reference numbers will be used throughout the drawings to refer to the same or like parts.

It should be noted that, the parts/components in the figures, e.g., thicknesses of the films, are only for illustrative purposes and do not reflect the actual ratios or dimensions of the structures.

### First Embodiment

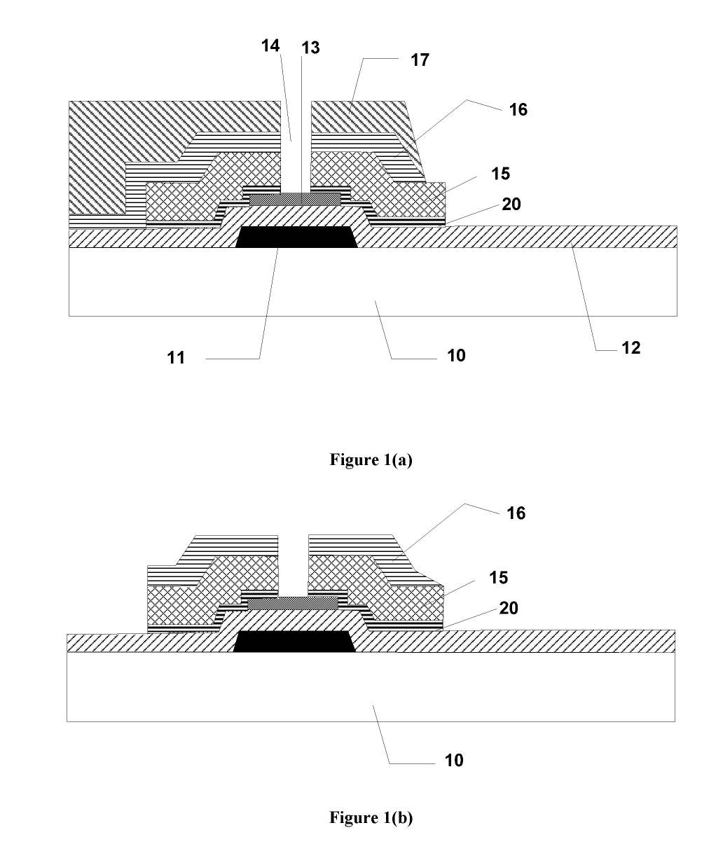

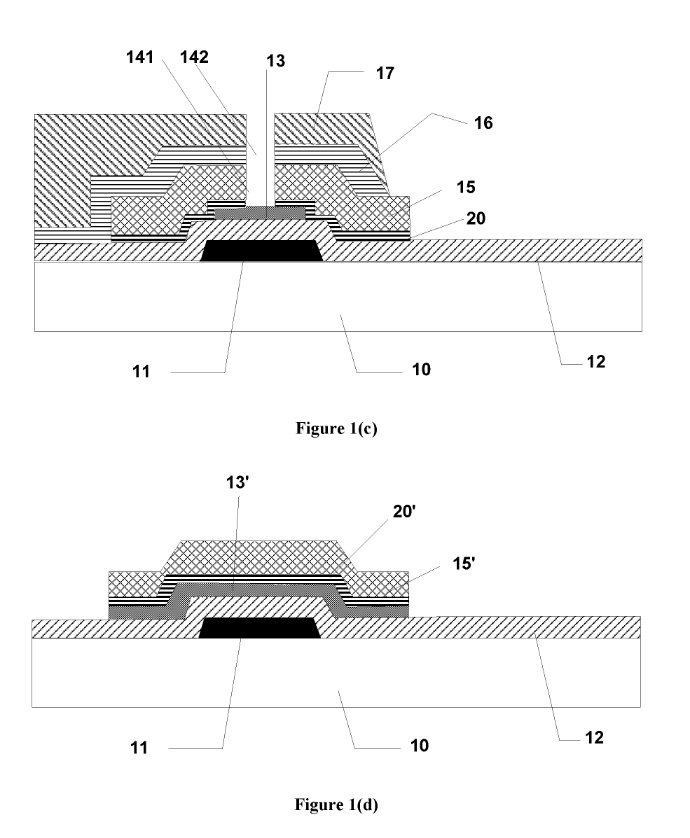

One aspect of the present disclosure provides a TFT. For illustrative purposes, the structure of only one TFT is shown in each of FIGS. 1(a) to (d) to illustrate the parts and related functions of the TFT. As shown in FIG. 1(a), the TFT may include a substrate 10, a gate electrode 11 on the substrate 10, and a gate insulating layer 12 on the gate electrode 11. The TFT may further include an active layer 13 on the gate insulating layer 12, and a source and drain electrode 15 on the gate insulating layer 12. The TFT may further include a protection layer 16 on the source and drain electrode 15, and an opening 14. The opening 14 may be through the protection layer 16 and the source and drain electrode 15. The opening 14 may correspond to a region of the active layer 13 between the source and drain electrode 15. The opening 14 may expose the channel region.

In some embodiments, the TFT may further include a barrier layer 20 between the gate insulating layer 12 and the source and drain electrode 15, covering a portion of the active layer 13 and exposing the channel region of the active layer 13. In this embodiment, the source and drain electrode 15 may be formed on the barrier layer 20. The barrier layer 20 may be used to protect the active layer 13 from being etched or eroded during the formation or etching process of the source and drain electrode 15.

As used herein, the term “protection layer” may be referred to as a layer for protecting one or more layers formed adjacent to the protection layer from being oxidized. For example, the protection layer 16 may protect the source and drain electrode 15 from being oxidized during the fabrication process. In some embodiment, the active layer 13 may be an oxide semiconductor layer 13. The protection layer 16 is not in direct contact with the oxide semiconductor layer 13 and further protects the oxide semiconductor layer 13.

As such, the protection layer may be formed on the source and drain electrode to prevent the source and drain electrode from being oxidized during the TFT fabrication process. Adverse effect to the performance of the TFT may be avoided or reduced.

Because the protection layer is disposed on the source and drain electrode, contact between the protection layer and the semiconductor oxide, i.e., the material for forming the active layer, can be avoided. Also, the barrier layer of the TFT may protect the active layer from being eroded or damaged during the etching for forming the source and drain electrode. Adverse effect to the semiconductor properties of the semiconductor oxide can be further avoided. Adverse effect to the performance of the formed TFT can be reduced or avoided. The protection layer may prevent the source and drain electrode from being oxidized, and the barrier layer may protect the active layer from being affected by substances such as one or more of water/moisture, hydrogen, and oxygen in subsequent fabrication steps. The performance of the formed TFT can be improved.

Further, in some embodiments, as shown in FIG. 1(a), the TFT may further include a resin layer 17 on the protection layer 16. The orthogonal projection of the resin layer 17 on the substrate 10 may overlap with the orthogonal projection of the protection layer 16 on the substrate 10.

In the TFT provided by the embodiments of the present disclosure, the resin layer 17 may be used as a mask, e.g., an etch mask, to form the protection layer 16.

In some embodiments, in the TFT provided by the embodiments of the present disclosure, the thickness of the resin layer 17 may be between about 1.0 to about 4.0 μm. The specific thickness of the resin layer 17 should be determined or adjusted according to different applications and designs and should not be limited by the present disclosure.

In the TFT provided by the embodiments of the present disclosure, the protection layer 16 may also be formed by a separate mask.

In the TFT provided by the embodiments of the present disclosure, as shown in FIG. 1(b), the orthogonal projection of the source and drain electrode 15 on the substrate 10 may overlap with the orthogonal projection of the protection layer 16 on the substrate 10. The orthogonal projection of the barrier layer 20 on the substrate 10 may overlap with the orthogonal projection of the source and drain electrode 15 on the substrate 10.

In the TFT provided by the embodiments of the present disclosure, the protection layer 16 may be made of a non-metal material. The material for forming the protection layer 16 may be different from the material for forming the source and drain electrode 15. The specific materials for forming the protection layer 16 and the source and drain electrode 15 may be determined or adjusted according to different applications and designs and should not be limited by the present disclosure.

In the TFT provided by the embodiments of the present disclosure, the protection layer 16 may be made of one or more of any suitable insulating metal oxides, SiNₓ, SiON, SiC, and an organic material.

Because the source and drain electrode 15 may be made of copper, and may be easily oxidized when exposed in or having contact with oxygen ions, and may fall off when oxidized to a certain extent, the protection layer 16 may be formed over the source and drain electrode 15 in the disclosed TFT. Contact between the protection layer 16 and the active layer 13, i.e., made of a semiconductor oxide, may be avoided. Adverse effect to the semiconductor properties of the semiconductor oxide can be avoided or reduced. Adverse effect to the performance of the TFT may be further avoided or reduced. The protection layer 16 may also protect the source and drain electrode 15 from being oxidized. In the disclosed TFT, the source and drain electrode 15 may be made of copper or any other suitable metals. When the source and drain electrode 15 is made of other metals, the protection layer 16 may also prevent the source and drain electrode 15 from being oxidized.

Further, in the TFT provided by the present disclosure, the thickness of the protection layer 16 may be between about 200 Å to about 2000 Å. The thickness of the barrier layer 20 may be between about 20 Å to about 1000 Å. The specific thickness of the protection layer 16 and the barrier layer 20 may be determined or adjusted according to different applications and designs and should not be limited by the present disclosure.

Further, in the TFT provided by the present disclosure, the resin layer 17 and the protection layer 16 may be fabricated through one patterning process to form the opening 14. The patterning process may be any suitable patterning process such as a photolithography process and a follow-up etching process. The follow-up etching process may be a wet etching process.

In some embodiments, a barrier layer 20 may be formed between the active layer 13 and the source and drain electrode 15. In this embodiment, the source and drain electrode 15 may be formed on the barrier layer 20. The barrier layer 20 may be etched to expose the channel region of the active layer 13 after the opening 14 is formed. The barrier layer 20 may be made of suitable metals such as one or more of Mo, Ti, W, Mo alloys, and Ti alloys. The material for forming the barrier layer 20 may have a high etch selectivity over the material for forming the source and drain electrode 15, which is copper in one embodiment. Thus, when forming the opening 14, the etching of the source and drain electrode 15 would not significantly etch the barrier layer 20. The active layer 13 can be prevented from being eroded or etched by substances such as H₂O, H, and/O, in the subsequent fabrication steps. The barrier layer 20 may further be etched, e.g., through a dry etching process, to expose the channel region of the active layer 13 after the source and drain electrode 15 is formed. The material for forming the barrier layer 20 may also have a high etch selectivity over the semiconductor oxide, which is the material for forming the active layer 13. Thus, the channel region of the active layer 13 can be exposed after the portion of the barrier layer 20 corresponding to the channel region of the active layer 13 is etched away, and the active layer 13 may be prevented from being eroded or damaged.

In the patterning process, as shown in FIG. 1(c), for illustrative purposes, the opening 14 may be divided into a first opening 141 and a second opening 142. The first opening 141 may be a removed portion of the source and drain electrode 15 that corresponds to the channel region of the active layer 13. The second opening 142 may be a removed portion of the protection layer 16 that corresponds to the channel region of the active layer 13. In this embodiment, the resin layer 17, the protection layer 16, the first opening 141, and the second opening 142 may be formed by a single patterning process.

The fabrication of the first opening 141 and the second opening 142 may be illustrated by comparing FIGS. 1(c) and 1(d). For viewing simplicity, the resin layer 17, shown in FIG. 1(c), is not shown in FIG. 1(d). As shown in FIG. 1(d), before the fabrication steps to form the first opening 141, the active layer 13 and the source and drain electrode 15 maybe formed through one patterning process. An active film may be formed on the gate electrode 11 for forming the active layer 13 subsequently. A source and drain electrode film may be formed on active film for forming the source and drain electrode 15 subsequently. In one embodiment, a barrier film may be formed on the active film, and the barrier film may be configured for forming the barrier layer 20 subsequently. The barrier film may cover the channel region of the subsequently-formed active layer 13. The active film, the barrier film, and the source and drain electrode film may be patterned to form a patterned active film 13′, a patterned barrier film 20′, and a patterned source and drain electrode film 15′. The patterned active film 13′ may be the active layer 13. The patterned source and drain electrode film 15′ may be patterned to form the source and drain electrode 15. The patterned barrier film 20′ may be patterned to form the barrier layer 20.

In this embodiment, the patterned source and drain electrode film 15′ may not contain the first opening 141 or may not be etched to form the first opening 141. That is, when the patterned source and drain electrode film 15′ is formed, the first opening 141 and the second opening 142 may not be formed. The portion of the patterned barrier film 20′, covering the channel region of the subsequently-formed active layer 13, may be removed to expose the channel region after the first opening 141 and the second opening 412 are formed. The barrier layer 20, shown in FIGS. 1(a)-(c), may be then formed.

Further, in the TFT provided by the present disclosure, the active layer 13 may be made of a suitable metal oxide. The specific type of the material used to form the active layer 13 should not be limited by the present disclosure.

Specifically, in the TFT provided by the present disclosure, the metal oxide may include one or more of gallium zinc oxide (GZO), indium gallium zinc oxide (a-IGZO), hafnium indium zinc oxide (HIZO), indium zinc oxide (IZO), amorphous indium zinc oxide (a-IZO), zinc oxide:fluorine (ZnO:F), indium oxide:tin (In₂O₃:Sn), indium oxide:molygdenum (In₂O₃:Mo), cadmium tin oxide (Cd₂SnO₄, Cd—Sn—O), zinc oxide:aluminum (ZnO:Al), titanium oxide:niobium (TiO₂:Nb), etc. The metal oxide described above may have properties of a semiconductor. The specific material to form the metal oxide should be determined according to different designs/applications and should not be limited by the present disclosure.

Further, in one embodiment, in the TFT provided by the present disclosure, the thickness of the active layer 13 may be controlled to be between about 50 Å to about 1000 Å. The specific thickness of the active layer 13 should be determined according to different designs/applications and should not be limited by the present disclosure.

In some embodiments, to reduce the impedance of the source and drain electrode 15, in the TFT provided by the present disclosure, the source and drain electrode 15 may be made of copper (Cu), which has a sufficiently low resistance.

Further, in one embodiment, in the TFT provided by the present disclosure, the thickness of the source and drain electrode 15 may be controlled to be between about 2000 Å to about 8000 Å. The specific thickness of the source and drain electrode 15 should be determined according to different designs/applications and should not be limited by the present disclosure.

In some embodiments, to reduce the impedance of the gate electrode 11, in the TFT provided by the present disclosure, the gate electrode 11 may be made of copper, which has a sufficiently low resistance.

Specifically, in one embodiment, in the TFT provided by the present disclosure, the thickness of the gate electrode 11 may be controlled to be between about 2000 Å to about 8000 Å. The specific thickness of the gate electrode 11 should be determined according to different designs/applications and should not be limited by by the present disclosure.

Further, in the TFT provided by the present disclosure, the gate insulating layer 12 maybe made of one or more of nitride and oxynitride compound. The specific material to form the gate insulating layer 12 should be determined according to different designs/applications and should not be limited by the present disclosure.

Further, in the TFT provided by the present disclosure, the thickness of the gate insulating layer 12 may be controlled to be between about 300 Å to about 3000 Å. The specific thickness of the gate insulating layer 12 should be determined according to different designs/applications and should not be limited by the present disclosure.

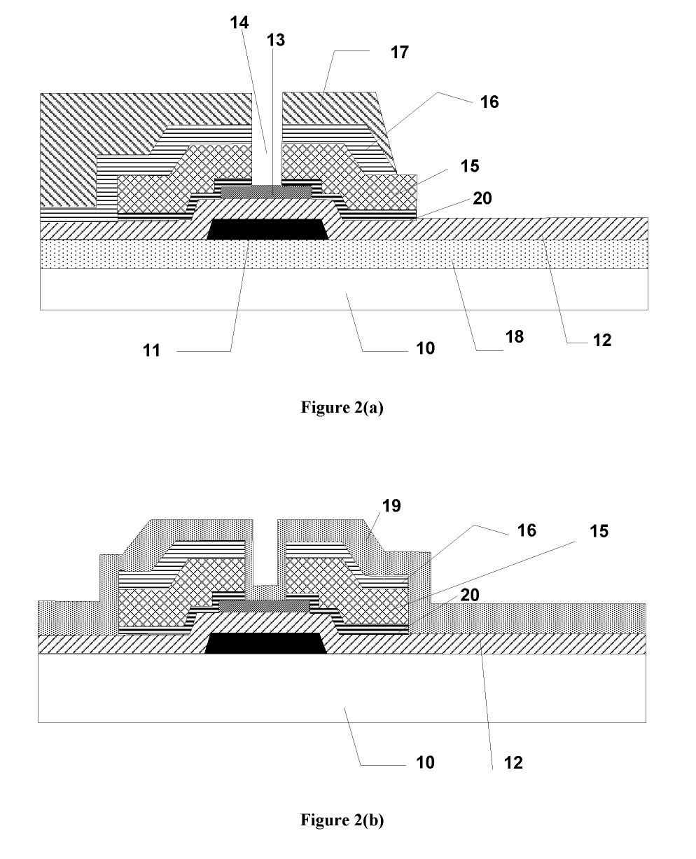

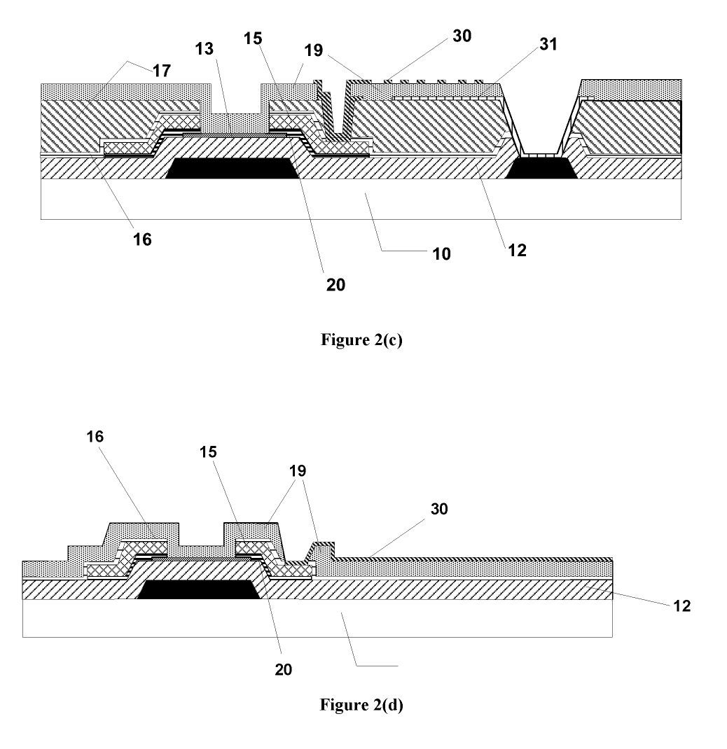

Further, to increase or improve the adhesion between the gate electrode 11, made of copper, and the substrate 10, the TFT provided by the present disclosure, as shown in FIG. 2(a), may further include a buffer layer 18 between the gate electrode 11 and the substrate 10.

Further, to increase or improve the resistance, of the to be formed TFT, to the moisture and water in the outside environment, and further improve the stability of the to be formed TFT, the TFT provided by the present disclosure, as shown in FIG. 2(b), may further include a passivation layer 19 covering the protection layer 16 and the gate insulating layer 12. The passivation layer 19 may cover at least the portion of the active layer 13 corresponding to the opening 14, the protection layer 16, and the gate insulating layer 12. In some embodiments, the passivation layer 19 may cover at least the portion of the active layer 13 corresponding to the opening 14 and the protection layer 16.

The passivation layer 19 may be made of a suitable material such as one or more of oxide and oxynitride compounds. The material for forming the passivation layer 19 may be properly selected so that the contact between the passivation layer 19 and the active layer 13, e.g., made of metal oxide, may not affect or adversely affect the properties of the active layer 13.

Further, in the TFT provided by the present disclosure, the to-be-formed TFT may be operated under twisted nematic (TN) mode or advanced super dimension switch (ADS) mode.

For example, a TFT operated under the ADS mode, as shown in FIG. 2(c), may further include one or more pixel electrodes 30 and a common electrode 31. The pixel electrodes 30 and the common electrode 31 may be separated by the passivation layer 19. The materials for forming the pixel electrodes 30 and the common electrode 31 may include, but be not limited to, a single-layered film made of one or more of ITO and IZO, or a multiple-layered film made of one or more of ITO and IZO. The specific structure of the pixel electrodes 30 and the common electrode 31 may be determined or adjusted according to different applications/designs and should not be limited by the present disclosure. In FIG. 2(c), the protection layer is labeled as 16, the source and drain electrode is labeled as 15, and the resin layer is labeled as 17.

A TFT operated under the TN mode, as shown in FIG. 2(d), may further include a pixel electrode 30. The pixel electrode 30 may be positioned on the passivation layer 19. The materials for forming the pixel electrodes 30 may include, but be not limited to, a single-layered film made of one or more of ITO and IZO, or a multiple-layered film made of one or more of ITO and IZO.

Another aspect of the present disclosure provides an array substrate. The array substrate may include one or more of the disclosed TFTs. The configuration of the array substrate and the TFTs on the array substrate may be according to the description above and is not repeated herein.

Specifically, the array substrate provided by the present disclosure may be used in liquid crystal display (LCD) panels. The array substrate may also be used in organic light-emitting diode (OLED) display panels. The specific display panels containing the disclosed array substrate should not be limited by the present disclosure.

The present disclosure further provides a display panel. The display panel may include one or more of the display array substrates. The display panel may be an LCD panel or an OLED display panel. Other necessary parts, for the operation of the display panel, should be known to those skilled in the art and are not repeated herein. These parts should also not be limited by the present disclosure. The configuration of the display panel may be referred to the embodiments described above and is not repeated herein.

### Second Embodiment

The present disclosure further includes a method for fabricating the TFT described in the First Embodiment. For illustrative purposes, only one TFT is used to describe the method. According to the method, the fabrication of the TFT may include the fabrication of the active film, the source and drain electrode film, and the protection film. Optionally, the fabrication of the TFT may also include the fabrication of the barrier film. The active film may be fabricated to subsequently form the active layer. The source and drain electrode film may be fabricated to subsequently form the source and drain electrode. The protection film may be fabricated to subsequently form the protection layer. The barrier film may be fabricated to subsequently form the barrier layer. The fabrication of the TFT may further include forming the first opening and the second opening. The first opening may be a removed portion of the source and drain electrode film that corresponds to the channel region of the active layer. The second opening may be a removed portion of the protection film that corresponds to the channel region of the active layer. The first opening and the second opening may be fabricated through one patterning process.

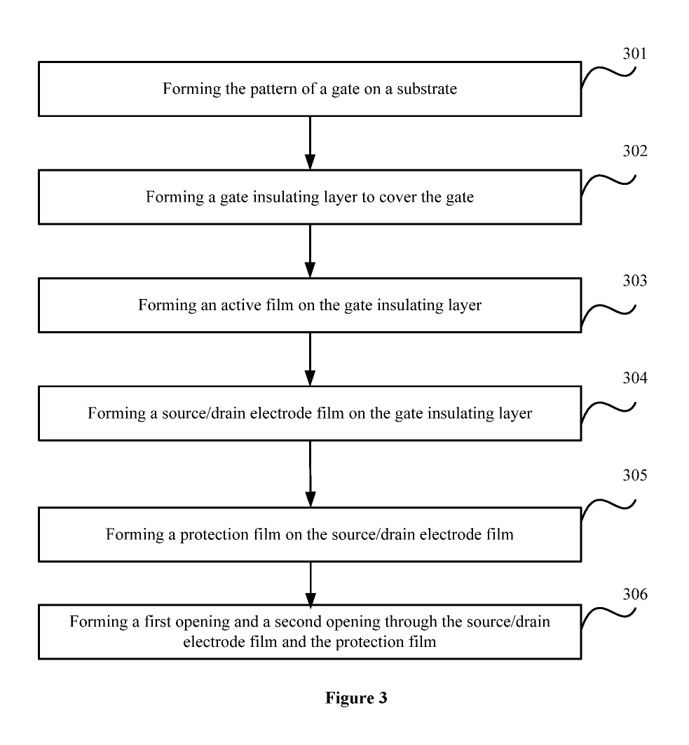

An exemplary process flow to form the TFT is shown in FIG. 3. The process may include steps S301 to S306.

In step S301, the pattern of a gate electrode is formed on a substrate.

The substrate may be one or more of a transparent glass substrate and a quartz substrate.

Further, in one embodiment, to improve or increase the adhesion between the gate electrode and the substrate, in some embodiments, a buffer layer may often be formed on the substrate before the formation of the gate electrode.

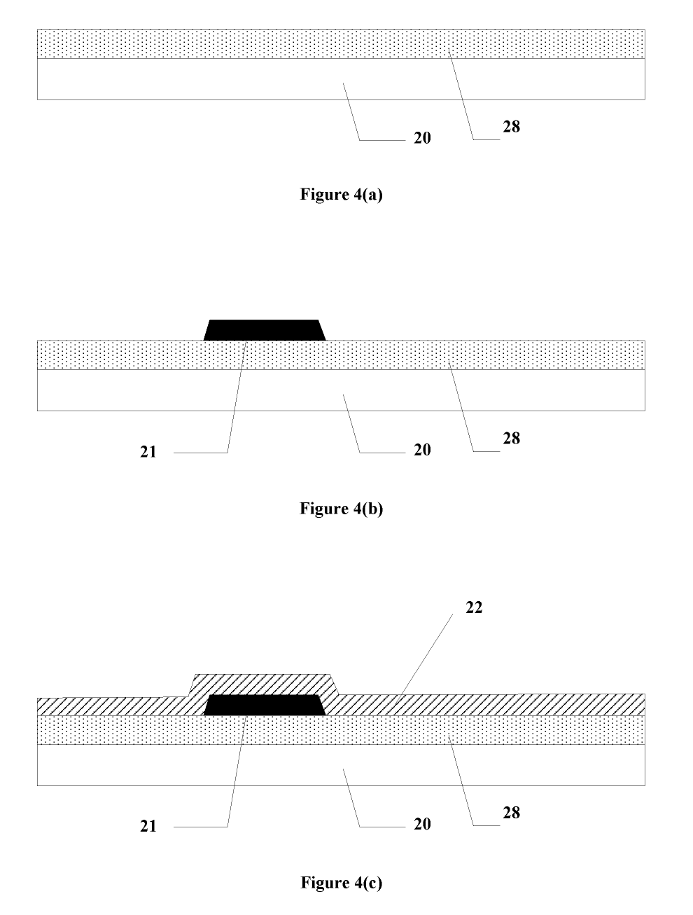

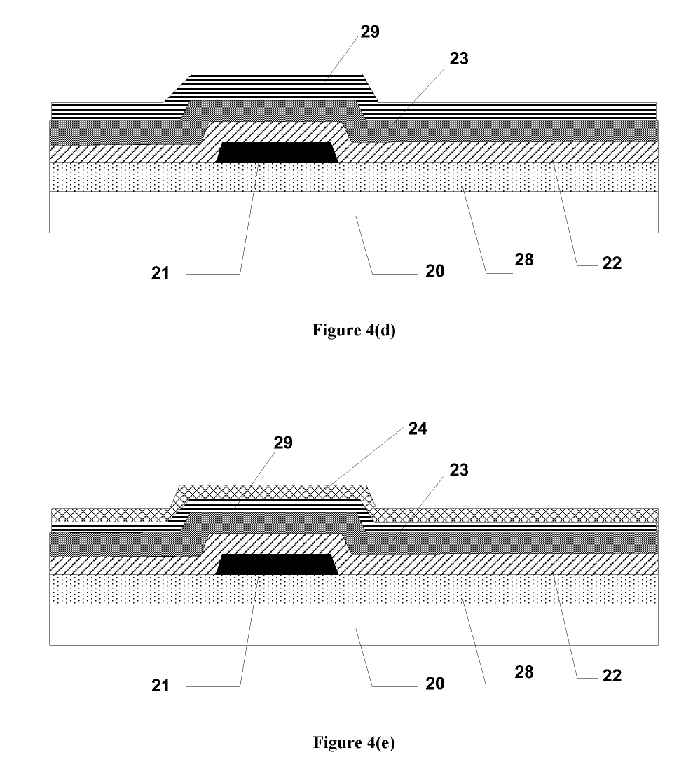

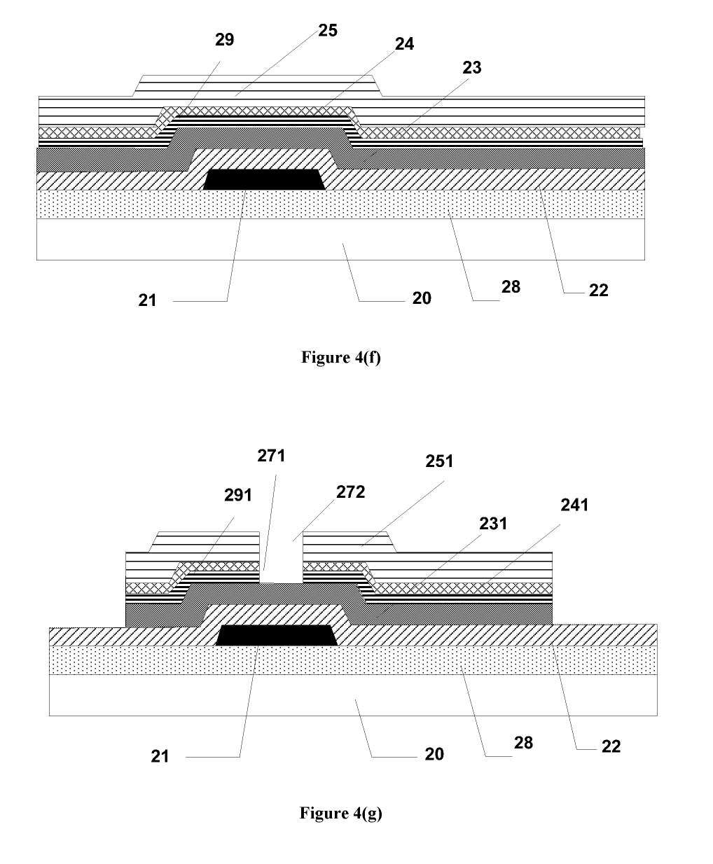

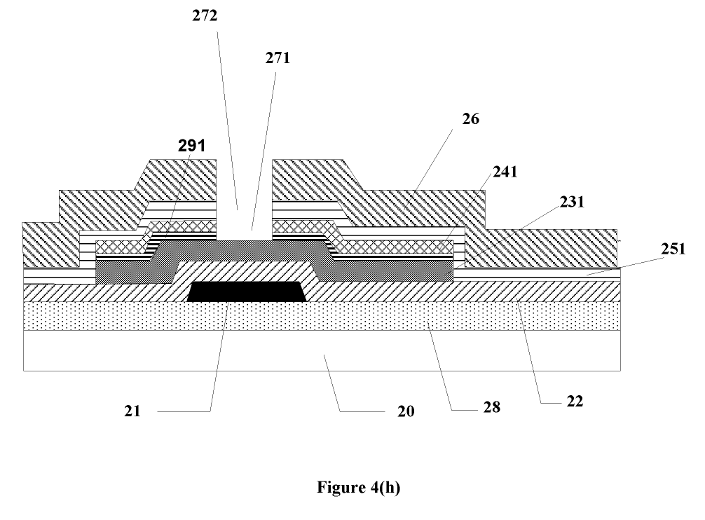

Specifically, as shown in FIG. 4(a), a buffer layer 28 may be formed on the substrate 20. Further, as shown in FIG. 4(b), the pattern of a gate electrode 21 may be formed on the buffer layer 28.

Specifically, in the method provided by the present disclosure, the gate electrode 21 may be made of copper, with a sufficiently low resistance. In one embodiment, a Cu thin film, with a thickness of about 2000 Å to about 10000 Å, may be deposited on the substrate using a suitable deposition process such as one or more of sputtering and thermal evaporation. The Cu thin film may be patterned to form the gate electrode 21 and gate scanning lines (not shown) to form the gate electrode pattern. The patterning process to fabricate the gate electrode pattern may include a photolithography process with a subsequent etching process.

The buffer layer 28 may improve the adhesion between the gate electrode 21, made of Cu, and the substrate 20.

In step S302, a gate insulating layer is formed to cover the gate electrode.

The gate insulating layer 22 may be formed, as shown in FIG. 4(c). In one embodiment, in the method provided by the present disclosure, plasma enhanced chemical vapor deposition (PECVD) may be used to form the gate insulating layer 22. The gate insulating layer 22 may have a thickness of about 300 Å to about 3000 Å.

Specifically, the gate insulating layer 22 may be made of one or more of nitride and oxynitride compounds. The thickness of the gate insulating layer 22 may be controlled to be between about 300 Å to about 3000 Å. The specific material to form the gate insulating layer 22 should not be limited by the present disclosure. The gases used to form the gate insulating layer 22 may include SiH₄, a mixture of NH₃, and N₂, a mixture of SiH₂Cl₂, NH₃, N₂, and SiH₄, and a mixture of NH₃, N₂O, and N₂. The specific types of gases to form the gate insulating layer 22 should be determined or adjusted according to different embodiments and applications and should not be limited by the present disclosure.

In step S303, an active film is formed on the gate insulating layer.

As shown in FIG. 4(d), the active film 23 may be formed on the gate insulating layer 22. In one embodiment, a barrier film 29 may be formed on the active film 23. The active film 23 may be patterned subsequently to form the active layer. The barrier film 29 may be patterned subsequently to form a barrier layer. The patterning process may include a photolithography process and a follow-up etching process.

Specifically, in one embodiment, the active film 23 may be made of a metal oxide. The thickness of the active film 23 may be between about 50 Å to about 1000 Å. The specific thickness of the active film 23 should be determined or adjusted according to different embodiments and applications and should not be limited by the present disclosure.

In some embodiments, a barrier film may be formed on the active film. As shown in FIG. 4(d), the barrier film 29 may be formed on the active film and patterned subsequently to form the barrier layer. The barrier film 29 may be about 20 Å to about 1000 Å. The barrier film 29 may be made of suitable metals such as one or more of Mo, Ti, W, Mo alloys, and Ti alloys. The barrier film 29 may be formed by any suitable deposition process such as sputtering.

It should be noted that, the barrier layer may also be used to provide protection of the active film/layer when the active film/layer is not made of copper. The material for forming the barrier layer may have high etch selectivity over the materials for forming the source and drain electrode and the active film/layer, respectively. The specific materials of the barrier layer should not be limited by the present disclosure.

In step S304, a source and drain electrode film is formed on the gate insulating layer and the active film.

As shown in FIG. 4(e), in some embodiments, the source and drain electrode film 24 may be formed on barrier film 29.

In some embodiments, a barrier film 29 may not be formed on the active film 23. In this case, the source and drain electrode film 24 may be formed on the active film 23.

In step S305, a protection film is formed on the source and drain electrode film.

As shown in FIG. 4(f), the protection film 25 may be formed on the source and drain electrode film 24.

In step S306, a first opening and a second opening are formed through the source and drain electrode film and the protection film, where the first opening is the removed portion in the source and drain electrode film that corresponds to the channel region of the active layer, and the second opening is the removed portion in the protection film that corresponds to the channel region of the active layer.

The first opening and the second opening may be fabricated through one patterning process. The patterning process may include photolithography process and a wet etching process.

In step S306, two processes may be used to form the first opening 271 and the second opening 272. The formed structure is shown in FIG. 4(g).

According to the first process, one patterning process is used to form the active layer, the source and drain electrode, and the protection layer, of the TFT.

Specifically, as shown in FIG. 4(g), one patterning process may be used to form the active layer 231, the source and drain electrode 241, and the protection layer 251, of the TFT.

In some embodiments, when a barrier film 29 is formed between the active film 23 and the source and drain electrode film 24, a first patterning process may be used to form the source and drain electrode 241 and the protection layer 251, of the TFT. The first patterning process may include a photolithography and a wet etching process. The first opening 271 and the second opening 272 may be formed. The barrier film 29 may cover the channel region of the active layer 231. A dry etching process may be performed to remove the portion of the barrier layer 291 covering the channel region of the active layer and expose the active layer 231 at the channel region after the first opening 271 and the second opening 272 are formed, and the barrier layer 291 may be formed. The material for forming the barrier layer 291 may have high etch selectivity over the source and drain electrode 241 and the active layer 231, respectively.

In some embodiments, one or more of a halftone mask and a gray-scale mask may be used to form the active layer 231, the source and drain electrode 241, the barrier layer 291, and the protection layer 251, of the TFT.

According to the second process, before the first opening is formed, the active layer 231, a patterned barrier film, and a patterned source and drain electrode film, without the first opening, are formed through one patterning process. The protection film and a resin film may be formed on the patterned source and drain electrode film. Another patterning process is used to form a resin layer, the protection layer 251, the first opening 271, and the second opening 272, of the TFT. In this case, the portion of the patterned barrier film covering the channel region of the active layer 231 may be removed, e.g., through a dry etching process, after the first opening 271 and the second opening 271 of the TFT are formed. The detailed description of the second process may be referred to the description of FIG. 1(d) and is not repeated herein.

In the second process, the thickness of the resin layer may be between about 1.0 to about 4.0 μm. The specific thickness of the resin layer may be determined and/adjusted according to different designs and applications, and should not be limited by the present disclosure.

Specifically, one patterning process may be used to form the active layer 231, the barrier layer 291, and the source and drain electrode 241, without the first opening, by patterning the structure shown in FIG. 1(d). Another patterning process may be used to form the resin layer 26, the protection layer 251, the first opening 271, and the second opening 272, of the TFT. The structure shown as FIG. 4(h) can be obtained.

In some embodiments, the method may further include forming a passivation layer (not shown in FIG. 4h). The passivation layer may at least cover the protection layer, the portion of the active layer corresponding to the first opening 271 and the second opening 272, and the gate insulating layer 22, of the TFT. The structure of the TFT with the passivation layer may be referred to FIG. 2(b). In some embodiments, the passivation layer may at least cover the protection layer and the portion of the active layer 231 corresponding to the first opening 271 and the second opening 272, of the TFT.

The passivation layer may be formed as follows. After the protection layer 251 is formed, a passivation film may be deposited on the protection layer 251. A patterning process may be applied on the passivation film to form the passivation layer. The passivation layer may at least cover the protection layer 251, the portion of the active layer 231 corresponding to the first opening 271 and the second opening 272, and the gate insulating layer 22, of the TFT.

In some embodiments, before the passivation film is deposited, the disclosed method may further include depositing a suitable material for forming pixel electrodes.

One or more pixel electrodes and a common electrode may be formed from the deposited material. The pixel electrodes and the common electrode may be separated by the passivation layer.

The materials for forming the pixel electrodes and the common electrode may include, but be not limited to, a single-layered film made of one or more of ITO and IZO, or a multiple-layered film made of one or more of ITO and IZO. The specific structure of the pixel electrodes and the common electrode may be determined or adjusted according to different applications/designs and should not be limited by the present disclosure.

The TFT with the common electrode and the pixel electrodes may be referred to FIGS. 2(c) and 2(d) and is not repeated herein.

The thickness of the protection layer 251 may be between 200 Å to 2000 Å. The specific thickness of the protection layer 251 may be determined or adjusted according to different applications and designs and should not be limited by the present disclosure.

Further, in the disclosed method, the active layer 231 may be made of a suitable metal oxide. The specific material for forming the active layer 231 may be determined or adjusted according to different applications and designs and should not be limited by the present disclosure.

Specifically, the metal oxide may include one or more of gallium zinc oxide

(GZO), indium gallium zinc oxide (a-IGZO), hafnium indium zinc oxide (HIZO), indium zinc oxide (IZO), amorphous indium zinc oxide (a-IZO), zinc oxide:fluorine (ZnO:F), indium oxide:tin (In₂O₃: Sn), indium oxide:molygdenum (In₂O₃:Mo), cadmium tin oxide (Cd₂SnO₄, Cd—Sn—O), zinc oxide:aluminum (ZnO:Al), titanium oxide:niobium (TiO₂:Nb), etc. The specific material to form the metal oxide should be determined according to different designs/applications and should not be limited by the present disclosure.

In one embodiment, in the TFT provided by the present disclosure, the thickness of the active layer 231 may be controlled to be between about 50 Å to about 1000 Å. The active layer 231 may be formed by a suitable deposition process such as sputtering. The specific thickness of the active layer 231 may be determined or adjusted according to different applications and designs and should not be limited by the present disclosure.

PECVD or any other suitable deposition process may be used to form the protection layer 251 on the substrate 20, with the source and drain electrode 241. The protection layer 251 may be used to prevent the source and drain electrode 241, made of copper, from being oxidized.

In the embodiments described above, as shown in FIGS. 4(c) to 4(h), the orthogonal projection of the source and drain electrode 241 on the substrate 20 may overlap with the orthogonal projection of the protection layer 251 on the substrate. The protection layer 251 may be made of a suitable non-metal material. The material for forming the protection layer 251 may be different from the material for forming the source and drain electrode 241. The specific materials for forming the protection layer 251 and the source and drain electrode 241 should be determined or adjusted according to different applications and designs and should not be limited by the present disclosure. In the TFT provided by the present disclosure, the protection layer 251 may be made of a suitable material such as one or more of SiNₓ and SiC. The protection layer 251 may also be an insulating metal oxide.

The gases used to form the protection layer 251 may include SiH₄, a mixture of NH₃ and N₂, a mixture of SiH₂Cl₂, NH₃, N₂, and SiH₄, and a mixture of NH₃, N₂O, and N₂. The specific types of gases to form the protection layer 251 should be determined or adjusted according to different embodiments and applications and should not be limited by the present disclosure.

The thickness of the protection layer 251 may be between 200 Å to 2000 Å. The specific thickness of the protection layer 251 may be determined or adjusted according to different applications and designs and should not be limited by the present disclosure.

The disclosed method may further including coating the protection layer 251 with a resin layer. The resin layer may be formed by any suitable deposition processes such as spin-on coating.

The thickness of the resin layer may be between about 1.0 to about 4.0 μm. The specific thickness of the resin layer should be determined or adjusted according to different applications and designs and should not be limited by the present disclosure.

A patterning process may be applied on the substrate, with the coated resin layer, to form an opening for the common electrode, openings for the pixel electrodes, and the channel region, of the TFT. The patterning process may include a suitable photolithography process. Further, a dry etching process may be used to etch away desired portions of the protection layer and the gate insulating layer. Thus, the patterns of the protection layer and the gate insulating layer may be formed with the pattern of the source and drain electrode through one patterning process. No additional patterning process is required. The fabrication cost may be reduced. The productivity for fabricating the TFTs may be improved.

In the disclosed method, PECVD or any other suitable deposition process may be used to deposit the passivation layer. The thickness of the passivation layer may be between about 1000 Å to about 3000 Å. Specifically, when the passivation layer is made of oxides of silicon, the reactant gases to form the passivation layer may be SiH₄ and N₂O. When the passivation layer is made of oxynitride compounds, the gases used to form the passivation layer may include SiH₄, a mixture of NH₃, and N₂, and a mixture of SiH₂Cl₂, NH₃, and N₂. The specific types of gases to form the passivation layer should be determined or adjusted according to different embodiments and applications and should not be limited by the present disclosure.

Embodiments of the present disclosure provide a TFT, a method for fabricating the TFT, and an array substrate and a display panel containing the TFT. Because the protection layer is positioned on the source and drain electrode, the protection layer may ensure the source is insulated from the drain when the TFT is turned off. The TFT may function properly. The protection layer may further prevent the source and drain electrode from being oxidized. The performance of the TFT may be improved. Further, the protection layer, positioned on the source and drain electrode, may not have contact with the active layer, made of a metal oxide. The barrier layer may protect the active layer from being eroded or etched by the subsequent fabrication steps. Adverse effect to the active layer may be avoided. The TFT may function properly.

Another aspect of the present disclosure provides a display apparatus. The display apparatus may incorporate one or more of the above-mentioned display panels. The display apparatus according to the embodiments of the present disclosure can be used in any product with display functions such as a television, an electronic paper, a digital photo frame, a mobile phone and a tablet computer.

It should be understood that the above embodiments disclosed herein are exemplary only and not limiting the scope of this disclosure. Without departing from the spirit and scope of this invention, other modifications, equivalents, or improvements to the disclosed embodiments are obvious to those skilled in the art and are intended to be encompassed within the scope of the present disclosure.

1-25. (canceled)

26. A thin-film transistor (TFT), comprising:
a gate electrode on a substrate;
a gate insulating layer covering the gate electrode;
an active layer having a channel region between a source and drain electrode;
the source and drain electrode on the gate insulating layer;
a protection layer on the source and drain electrode; and
an opening through the protection layer and the source and drain electrode, the opening exposing the channel region.

27. The TFT according to claim 26, wherein the protection layer is made of a non-metal material, different from a material for forming the source and drain electrode.

28. The TFT according to claim 27, wherein the protection layer is made of one or more of an insulating metal oxide, SiNₓ, SiON, SiC, and an organic material.

29. The TFT according to claim 26, wherein a thickness of the protection layer is between about 200 Å to about 2000 Å.

30. The TFT according to claim 26, further including a resin layer on the protection layer, an orthogonal projection of the resin layer on the substrate overlapping with an orthogonal projection of the protection layer on the substrate.

31. The TFT according to claim 30, wherein a thickness of the resin layer is between about 1.0 to about 4.0 μm.

32. The TFT according to claim 26, wherein an orthogonal projection of the source and drain electrode on the substrate overlaps with an orthogonal projection of the protection layer on the substrate.

33. The TFT according to claim 26, further including a passivation layer covering the protection layer and the channel region.

34. The TFT according to claim 26, further including a barrier layer between the active layer and the source and drain electrode, the barrier layer exposing the channel region.

35. The TFT according to claim 26, wherein a material for forming the barrier layer has high etch selectivity over a material for forming the active layer and a material for forming the source and drain electrode.

36. An array substrate, comprising the TFT according to claim 26.

37. A display panel, comprising the array substrate according to claim 36.

38. A method for fabricating a thin-film transistor (TFT), comprising:
forming a gate electrode on a substrate and a gate insulating layer covering the gate electrode;
forming an active film on the gate insulating layer for forming an active layer, the active layer having a channel region between a source and drain electrode;
forming a source and drain electrode film on the gate insulating layer for forming the source and drain electrode;
forming a protection film on the source and drain electrode film for forming a protection layer; and
forming an opening through the source and drain electrode film and the protection film, the opening corresponding to the channel region of the active layer.

39. The method according to claim 38, further including forming a barrier film between the active film and the source and drain electrode film, a material for forming the barrier film having high etch selectivity over a material for forming the active film and a material for forming the source and drain electrode film.

40. The method according to claim 39, wherein the barrier layer is made of Mo, Ti, W, Mo alloys, Ti alloys, or a combination thereof.

41. The method according to claim 38, wherein the active layer, the source and drain electrode and the protection layer are formed by one single patterning process.

42. The method according to claim 38, wherein the opening includes a first opening and a second opening, the first opening being formed by removing a portion of the source and drain electrode film that corresponds to the channel region of the active layer, and the second opening being formed by removing a portion of the protection film that corresponds to the channel region of the active layer.

43. The method according to claim 39, further including, removing a portion of the barrier layer to expose the channel region of the active layer after forming the first opening and the second opening.

44. The method according to claim 41, wherein a halftone mask, a gray-scale mask, or a combination of a halftone mask and a gray-scale mask is used to form the active layer, the source and drain electrode, and the protection layer.

45. The method according to claim 42, further including: before forming the first opening, forming the active layer and patterning the source and drain electrode film and the protection film.

46. The method according to claim 38, further including:
forming a resin layer on the protection layer, wherein the resin layer, the protection layer, and the opening are formed through one patterning process, the resin layer being used as a mask for forming the protection layer and the opening.

47. The method according to claim 38, further including:
forming a passivation layer on the protection layer, the passivation layer covering at least the protection layer and the channel region of the active layer corresponding to the opening.
